(19) United States
(12) Patent Application Publication
(10) Pub. No.: US 2023/0103177 A1
(43) Pub. Date: Mar. 30, 2023

(54) AIR BAFFLE STRUCTURE

(71) Applicant: KINPO ELECTRONICS, INC., New Taipei City (TW)

(72) Inventors: Long-Sing YE, NEW TAIPEI CITY (TW); Hung-Kai WANG, NEW TAIPEI CITY (TW)

(21) Appl. No.: 17/521,569

(22) Filed: Nov. 8, 2021

(30) Foreign Application Priority Data
Sep. 29, 2021 (TW) 110211448

(51) Int. Cl. G06F 1/20; H05K 7/20

(52) U.S. Cl. CPC G06F 1/20; H05K 7/20145; G06F 1/184

(57) ABSTRACT

An air baffle structure is provided for installing a motherboard and inside a case. The case includes an opening. The air baffle structure includes a pair of brackets and an air baffle cover. The pair of brackets are fixed on the case and disposed on two sides of the opening, and the motherboard is pluggably disposed between the pair of brackets. The air baffle cover is connected to tops of the pair of brackets and straddles the pair of brackets. Therefore, the air baffle cover may effectively guide the air to pass through the motherboard to dissipate heat of the motherboard, and the quantity of fans in the case is reduced.

### BACKGROUND OF THE DISCLOSURE

### Technical Field

The technical field relates to an air baffle cover installed on the opening of the case, and particularly relates to an air baffle structure.

### Description of Related Art

The stability of the work and life of products for electronic components such as the central processing unit (CPU) inside the server may be affected when overheating. As a result, in order to solve the problem of overheating, the heat source of electronic components is usually attached to the heat sink to transfer the heat by thermal conduction. Then, fans are used to dissipate the heat by forcible airflow to expel the heat out of the server.

However, since a large number of fans are used inside the server, the fans and their corresponding accessories need to be inspected and replaced regularly due to the limited service life which results in a high cost. Therefore, how to reduce the quantity of fans inside the server and reduce the cost are the objects in this disclosure.

In view of the above drawbacks, the inventor proposes this disclosure based on his expert knowledge and elaborate researches in order to solve the problems of related art.

### SUMMARY OF THE DISCLOSURE

This disclosure provides the air baffle structure, in which the air baffle cover may effectively guide the air to pass through the motherboard for dissipating heat and the quantity of fans in the case may be reduced.

In the embodiment of this disclosure, the air baffle structure for installing a motherboard and inside a case. The case includes an opening. The air baffle structure includes a pair of brackets and an air baffle cover. The pair of brackets are fixed on the case and disposed on two sides of the opening. The motherboard is pluggably arranged between the pair of brackets. The air baffle cover is connected to the top of the pair of brackets and straddles the pair of brackets.

According to the above, the air baffle cover may effectively guide the cold air to flow into the case and pass through the opening and the motherboard sequentially. The cold air absorbs the heat from the motherboard to assist the motherboard for dissipating heat, and the number of fans installed in the case may be reduced. Therefore, the air baffle structure has desirable heat dissipation efficiency, and the cost of assembly and maintenance of the case is reduced.

### BRIEF DESCRIPTION OF THE DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 is a perspective assembly view of the first embodiment of the air baffle structure in this disclosure.

FIG. 2 is a perspective assembly view of the first embodiment of the air baffle structure in this disclosure.

FIG. 3 is a perspective exploded view of the first embodiment of the air baffle structure in this disclosure.

FIG. 4 is a side view of the first embodiment of the air baffle structure in this disclosure.

FIG. 5 is a top view of the first embodiment of the air baffle structure in this disclosure.

FIG. 6 is a cross sectional view of the line 6-6 in FIG. 5.

FIG. 7 is a top view of operation status of the first embodiment of the air baffle structure in this disclosure.

FIG. 8 is a perspective assembly view of the second embodiment of the air baffle structure in this disclosure.

FIG. 9 is a perspective exploded view of the second embodiment of the air baffle structure in this disclosure.

FIG. 10 is a perspective assembly view of the third embodiment of the air baffle structure in this disclosure.

FIG. 11 is a perspective view of another operation status of the first, second and third embodiments of the air baffle structure in this disclosure.

FIG. 12 is a top view of another operation status of the first, second and third embodiments of the air baffle structure in this disclosure.

FIG. 13 is a perspective exploded view of the fourth embodiment of the air baffle structure in this disclosure.

FIG. 14 is a cross sectional view of the fourth embodiment of the air baffle structure in this disclosure.

FIG. 15 is a perspective exploded view of the fifth embodiment of the air baffle structure in this disclosure.

FIG. 16 is a cross sectional view of the fifth embodiment of the air baffle structure in this disclosure.

### DETAILED DESCRIPTION

The technical contents in this disclosure will become apparent with the detailed description of embodiments accompanied with the illustration of related drawings as follows. It is intended that the embodiments and drawings disclosed herein are to be considered illustrative rather than restrictive.

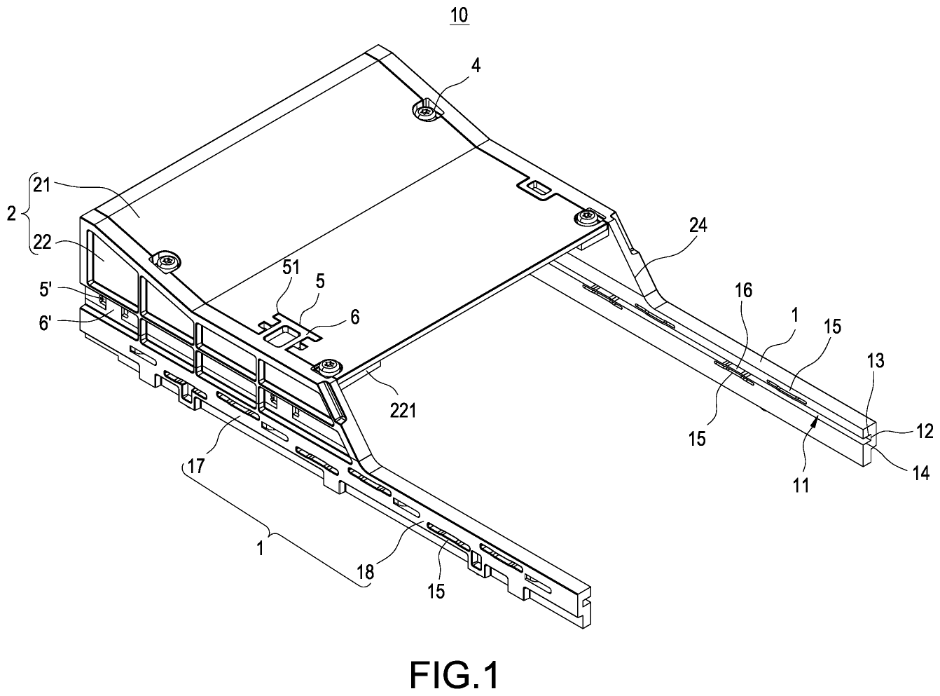

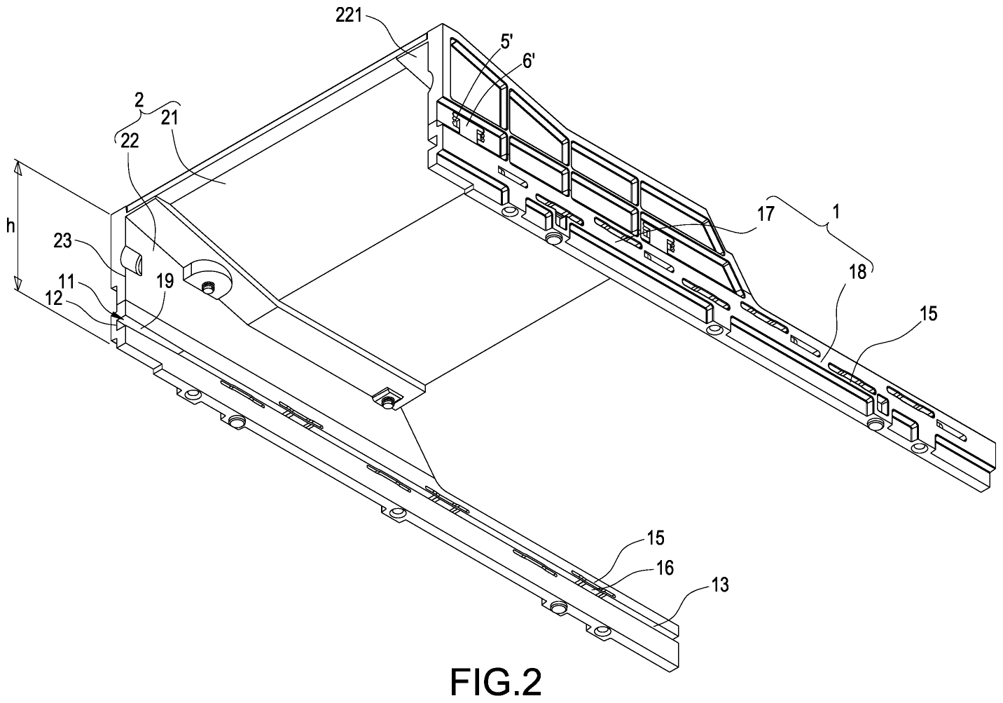

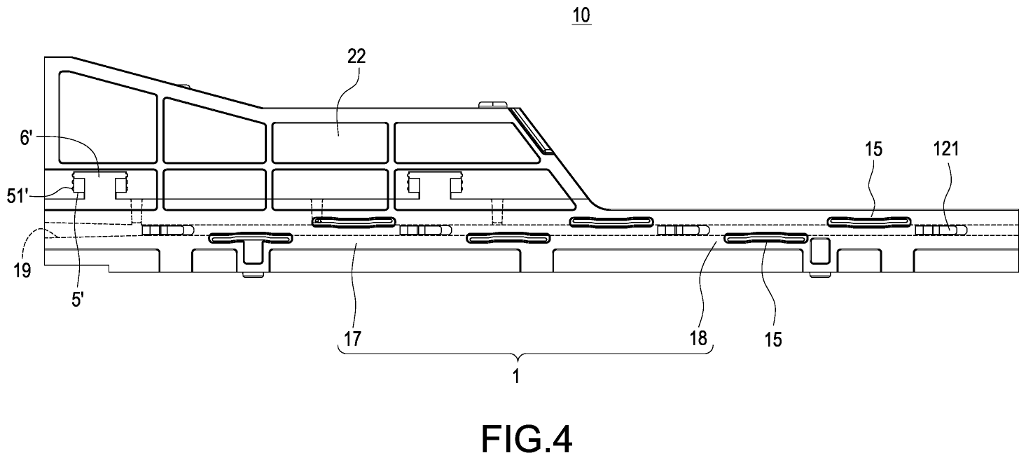

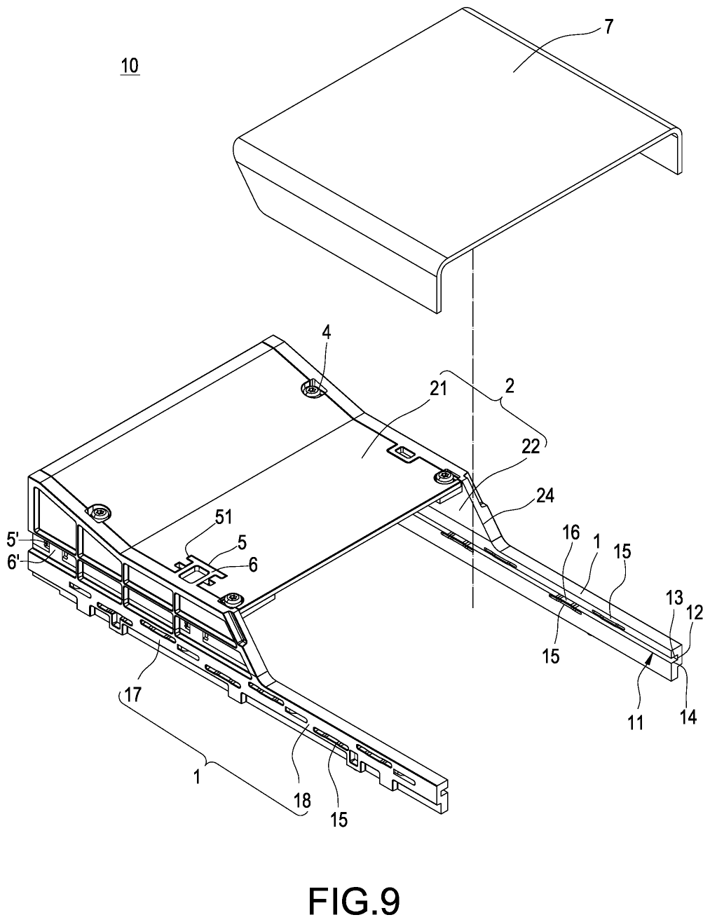

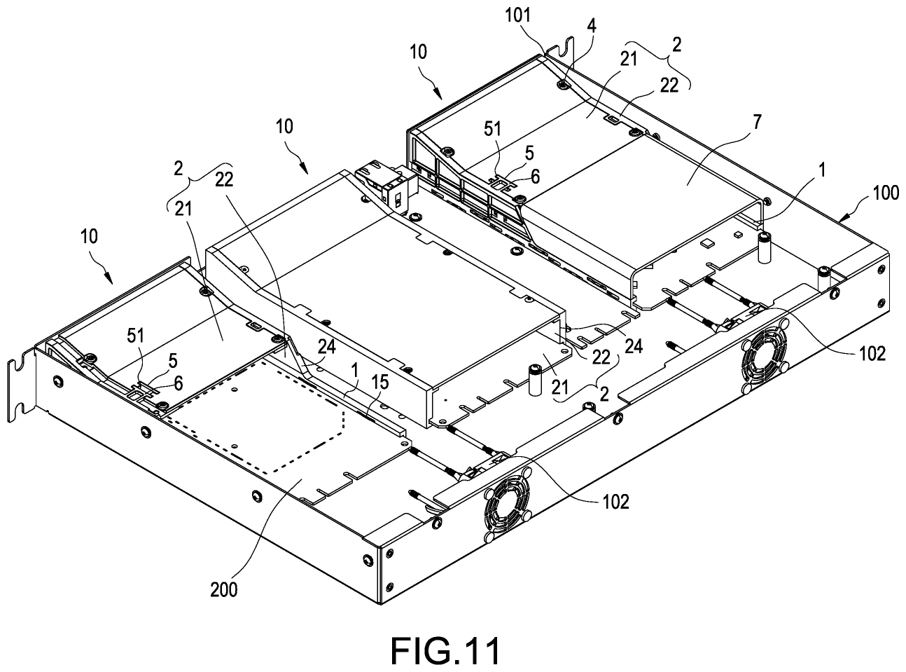

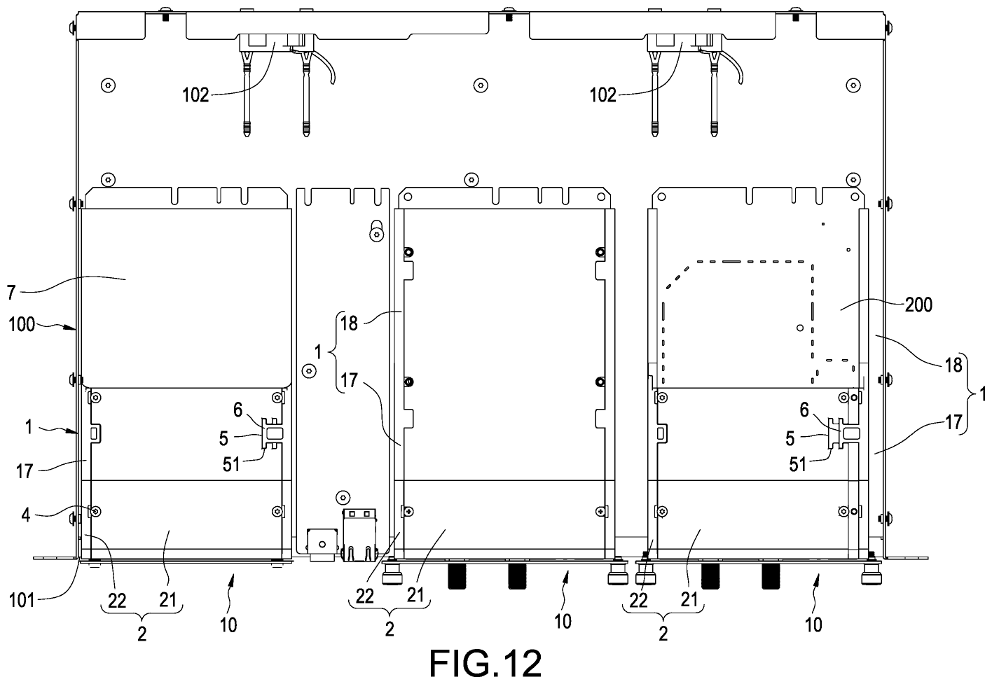

Please refer to FIG. 1 to FIG. 15. This disclosure provides a first, second and third embodiments of the air baffle structure for installing a motherboard 200 and inside a case 100. The case 100 includes an opening 101 disposed on one side and a plurality of fans 102 installed on the other side. The air baffle structure 10 mainly includes a pair of brackets 1 and an air baffle cover 2.

As shown in FIG. 1 to FIG. 12, the pair of brackets 1 are fixed on the case 100 and disposed on two sides of the opening 101, and two rail guiding grooves 11 are disposed on inner sides of the pair of brackets 1. Two sides of the motherboard 200 are pluggably embedded in the rail guiding grooves 11, thus the motherboard 200 is pluggably arranged between the pair of brackets 1.

More detailed is as follows. Each of the rail guiding grooves 11 includes an inner side wall 12, an inner top wall 13 and an inner bottom wall 14. A plurality of elastic arms 121 are punched from the outer side wall of each bracket 1 toward the inner side wall 12 of the rail guiding groove 11. As a result, a plurality of elastic arms 121 are protruded from each inner side wall 12, and the left and right sides of the motherboard 200 are clamped and limited by the plurality of elastic arms 121 to avoid resonance problems in the horizontal direction.

Additionally, a plurality of hollow grooves 15 disposed on the upper side and the lower side of the rail guiding groove 11 are punched from each of the brackets 1. A plurality of elastic bulges 16 are disposed corresponding to the plurality of hollow grooves 15 on the inner top wall 13 and the inner bottom wall 14. Each of the elastic bulges 16 may be compressed and deformed toward the hollow grooves 15. As a result, the upper side and lower side of the motherboard 200 are clamped and limited by the plurality of elastic bulges 16 to avoid resonance problems in the vertical direction.

Furthermore, each of the rail guiding grooves 11 includes a flaring section 19 adjacent to the opening 101, and an inner periphery size of the flaring section 19 is gradually increased in a direction toward the opening 101. The motherboard 200 may be quickly inserted into the rail guiding grooves 11 through the flaring section 19.

As shown in FIG. 1 to FIG. 12, the air baffle cover 2 is connected to the tops of the pair of brackets 1 and disposed between the pair of brackets 1. The air baffle cover 2 includes a top plate 21 and a pair of side plates 22 connected to two sides of the top plates 21.

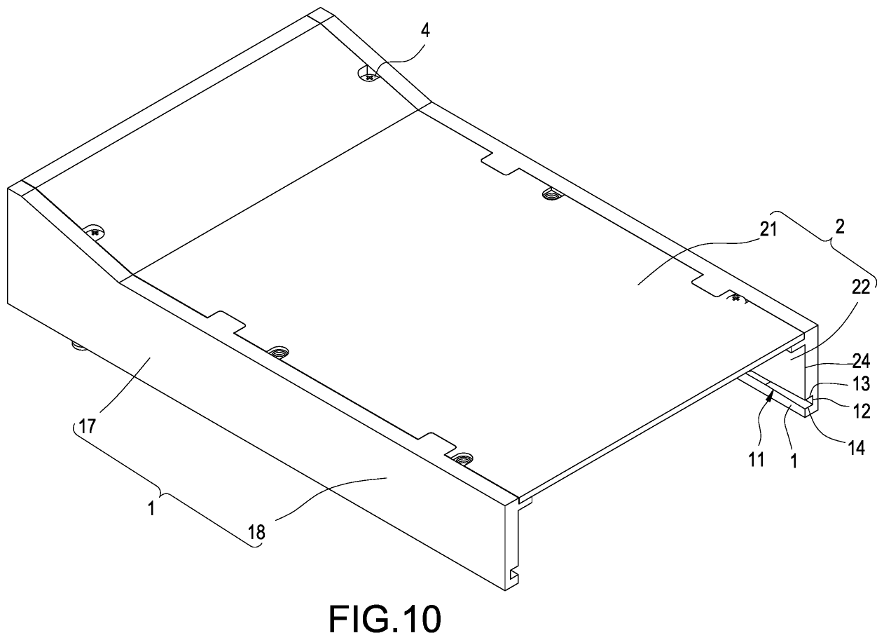

As shown in FIG. 1 to FIG. 9, they are the first, second and third embodiments of the air baffle structure in this disclosure, the pair of the side plates are detachably fixed to the tops of the pair of brackets 1, but not limited thereto. As shown in FIG. 10, it depicts the third embodiment of the air baffle structure 10 in this disclosure. The pair of side plates 22 may be integrally extended from the tops of the pair of brackets 1 (or formed in one piece).

Further, two ends of the air baffle cover 2 includes a first air opening 23 disposed adjacent to the opening 101 and a second air opening 204 disposed away from the opening 101. The height h of the top plate 21 is gradually decreased from the first air opening 23 toward the second air opening 24.

Additionally, one of the pair of side plates 22 is extended with an extension piece 221 laminated with the top plate 21. Either the top plate 21 or the extension piece 221 is provided with a zigzag groove 5, and the other one between the top plate 21 and the extension piece 221 is extended with a bump 6. In other words, if the zigzag groove 5 is disposed on the top plate 21, the bump 6 is disposed on the extension piece 221, and vice versa. An inner peripheral wall of the zigzag groove 5 is provided parallelly with a plurality of recesses 51, and the bump 6 is embedded in the zigzag groove 5 and selectively engaged with one of the recesses 51. Therefore, the relative position between the top plate 21 and the extension piece 221 may be adjusted through the bump 6 and the recesses 51, and then the interval between the pair of brackets 1 may be adjusted in multi-step. Hence, the motherboard 200 of different widths may be disposed between the pair of brackets 1.

Moreover, either the bracket 1 or the side plate 22 is provided with a zigzag groove 5′, and the other one between the bracket 1 and the side plate 22 each is provided with a bum 6′. In other words, if the zigzag groove 5′ is disposed on the side plate 22, the bump 6′ is disposed on the bracket 1, and vice versa. An inner peripheral wall of each zigzag groove 5′ is provided parallelly with a plurality of recesses 51′. Each bump 6′ is embedded in one of the zigzag grooves 5′ and selectively engaged with one of the recesses 51′. Therefore, the relative position between each bracket 1 and each side plate 22 may be adjusted through the bump 6′ and the recess 51′. Then, the height h of the top plate 21 may be adjusted in multi-step, and the air baffle cover 2 may be installed corresponding to the case 100 of different heights.

Furthermore, the front and the back of each bracket 1 includes a front section 17 and a rear section 18 respectively, and the front section 17 is disposed adjacent to the opening 101 with respect to the rear section 18. As shown in FIG. 1 to FIG. 9, they depict the first and second embodiments of the air baffle structure 10 in this disclosure. The air baffle cover 2 straddles between the front sections 17 of the pair of brackets 1, and the air baffle cover 2 covers the motherboard 200 entirely. As shown in FIG. 10, it depicts the third embodiment of the air baffle structure 10 in this disclosure. The air baffle cover 2 may straddle between the front sections 17 and the rear sections 18 of the pair of the bracket 1. As a result, the air baffle cover 2 only covers the front part of the motherboard 200.

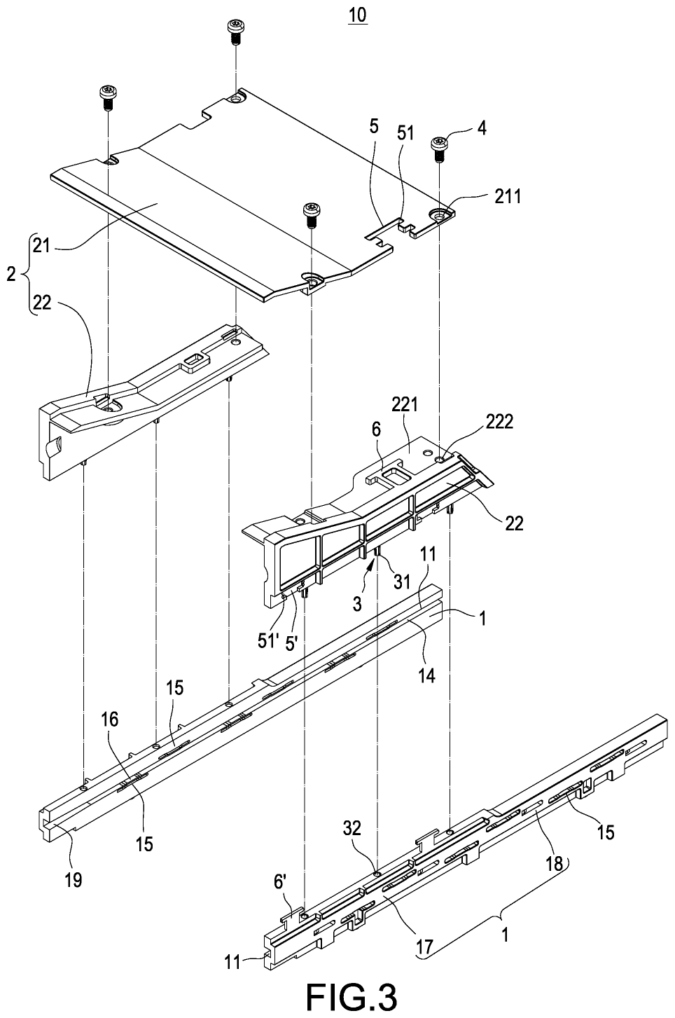

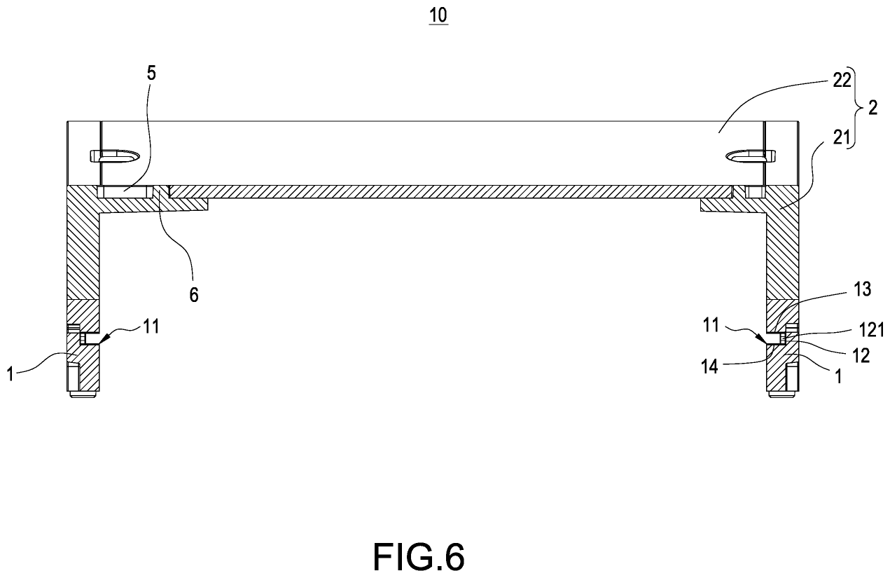

Please refer to FIG. 3 and FIG. 6. The air baffle structure 10 in this disclosure further includes a pair of detachable components 3. Each detachable component includes a plurality of posts 31 and a plurality of sockets 32. Each of the posts 31 is protruded from either the top of the bracket 1 or the bottom of the side plate 22. Each of the sockets 32 is recessed on the other one between the top of the bracket 1 and the bottom of the side plate 22. In other words, if each of the posts 31 is disposed on the side plate 22, each of the sockets 32 is disposed on the bracket 1, and vice versa. Each of the posts 31 is inserted in one of the sockets 32 in the vertical direction. Therefore, the pair of brackets 1 and the pair of side plates 22 are assembled with each other through the pair of detachable components 3.

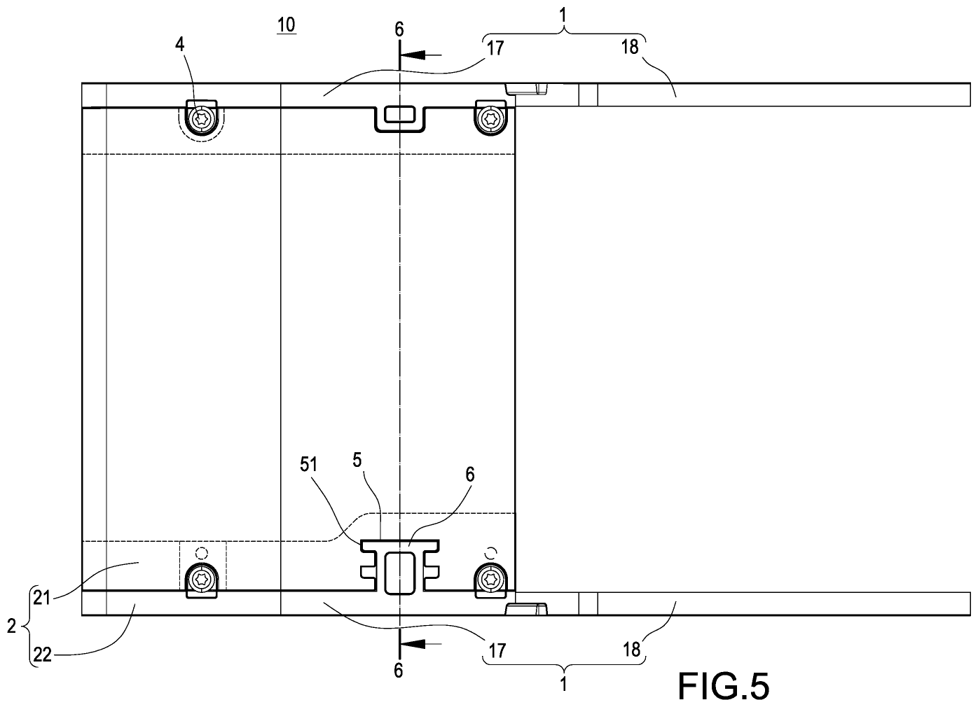

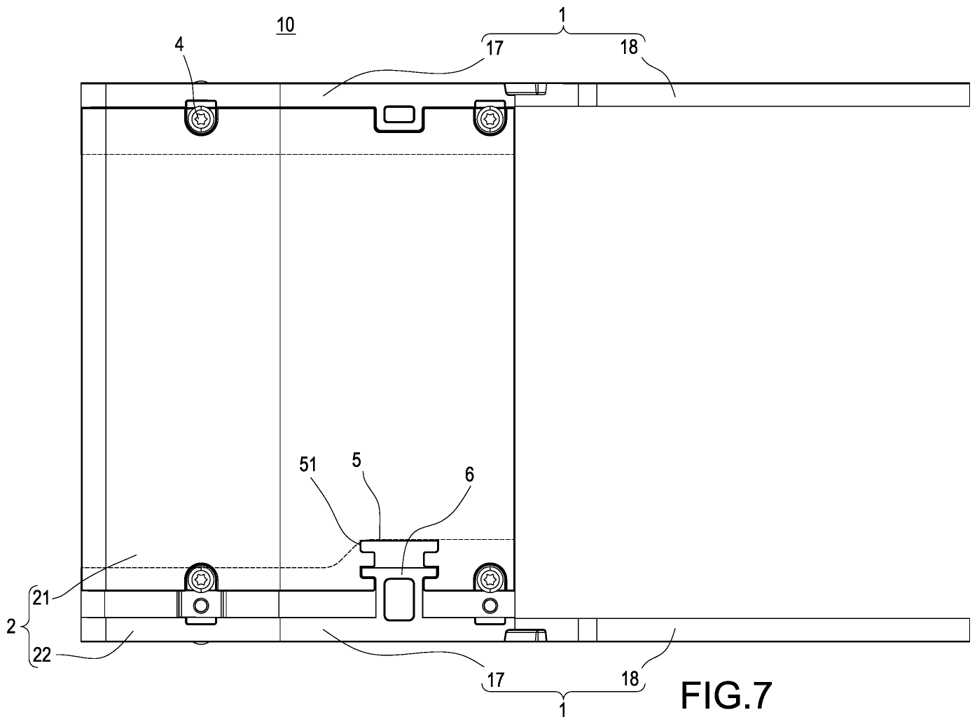

As shown in FIG. 1, FIG. 3, FIG. 5, and FIG. 7 to FIG. 12, the air baffle structure 10 in this disclosure further includes a plurality of fastening components 4. A plurality of first fastening holes 211 are disposed on the right and left sides of the top plate 21, and the top of each side plate 22 is provided a plurality of second fastening holes 22. Each fastening component 4 is inserted and fixed in one of the first fastening holes 211 and one of the second fastening holes 222. As a result, the top plate 21 is fixed on tops of the pair of side plates 22 to straddle the pair of side plates 22.

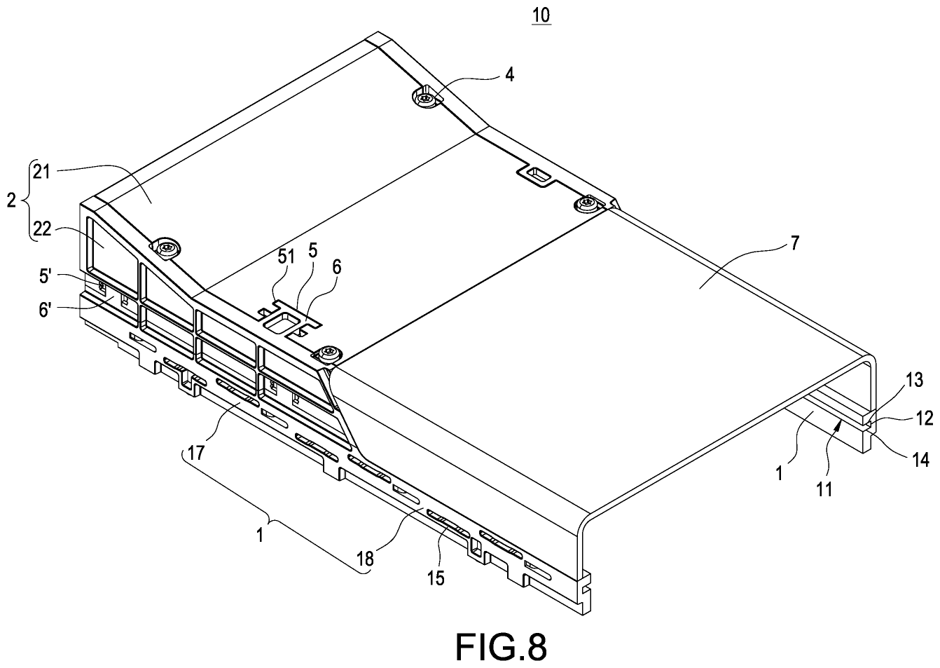

As shown in FIG. 8 to FIG. 9 and FIG. 11 to FIG. 12, the air baffle structure 10 in this disclosure further includes an auxiliary air baffle cover 7. When the air baffle cover 2 only straddles between the front sections 17 of the pair of brackets 1, the auxiliary air baffle cover 7 may be connected to the tops of the pair of brackets 1 and one end of the air deflector 2 to straddle the rear sections 18 of the pair of brackets 1. As a result, users may choose to cover the motherboard 200 entirely by the air baffle cover 2 and the auxiliary air baffle cover 7 together, or only the front part of the motherboard 200 is covered by the air baffle cover 2.

As shown in FIG. 1 to FIG. 15, they depict operation statuses of the first, second, and third embodiments of the air baffle structure 10 in this disclosure. The motherboard 200 is pluggably arranged between the pair of brackets 1, and the air baffle cover 2 is connected to tops of the pair of brackets 1 and straddles between the pair of brackets 1. Since the first air opening 23 of the air baffle cover 2 is disposed adjacent to the opening 101 of the case 100 and the second air opening 24 is disposed adjacent to the fans 102 of the case 100, the air baffle cover 2 may effectively guide the cold air to pass through the opening 101 and the motherboard 200 sequentially and flow into the case 100. The cold air absorbs the heat from the motherboard 200 to become the hot air when passing through the motherboard 200, and then the hot air is expelled from the case 100 by the fans 102 to dissipate heat of the motherboard 200. As a result, the number of fans installed in the case 100 may be reduced. Therefore, the air baffle structure 10 has desirable heat dissipation efficiency, and the cost of assembly and maintenance of the case 100 is reduced.

Additionally, the relative position between the top plate 21 and the extension piece 221 may be adjusted through the bump 6 and the recess 51. Thus, the motherboard 200 of different widths may be disposed between the pair of brackets 1. The relative position between each of the brackets 1 and the side plates 22 may be adjusted through the bump 6′ and the recess 51′, and the air baffle cover 2 may be installed corresponding to the case 100 of different heights. The air baffle cover 2 may completely cover the motherboard 200 or only cover the front part of the motherboard 200. Therefore, the air baffle structure 10 may be adjusted according to the width of the motherboard 200, the size of the case 100 or the heat source distribution, etc., to improve the convenience of use of the air baffle structure 10.

Moreover, as shown in FIG. 1 to FIG. 7, the pair of side plates 22 may be assembled or disassembled to the pair of brackets 1 through the pair of detachable components 3. That is, the air baffle cover 2 may be assembled or disassembled to the pair of brackets 1 through the pair of detachable components 3 to let users choose whether to install the air baffle cover 2 on the pair of brackets 1 according to actual situations to enhance the convenience of use of the air baffle structure 10.

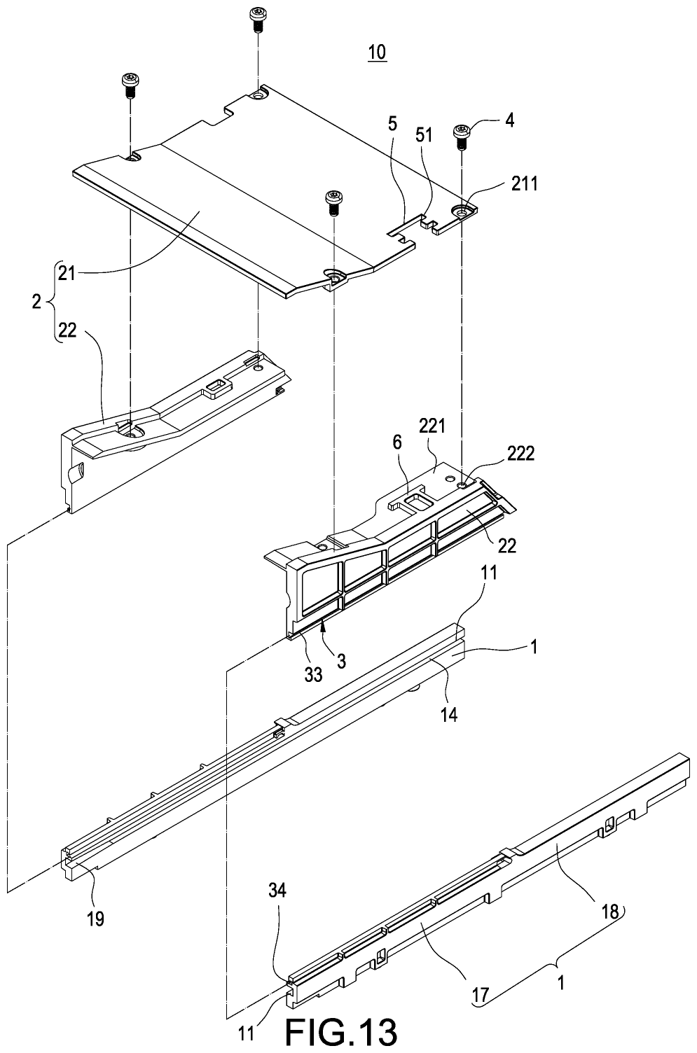

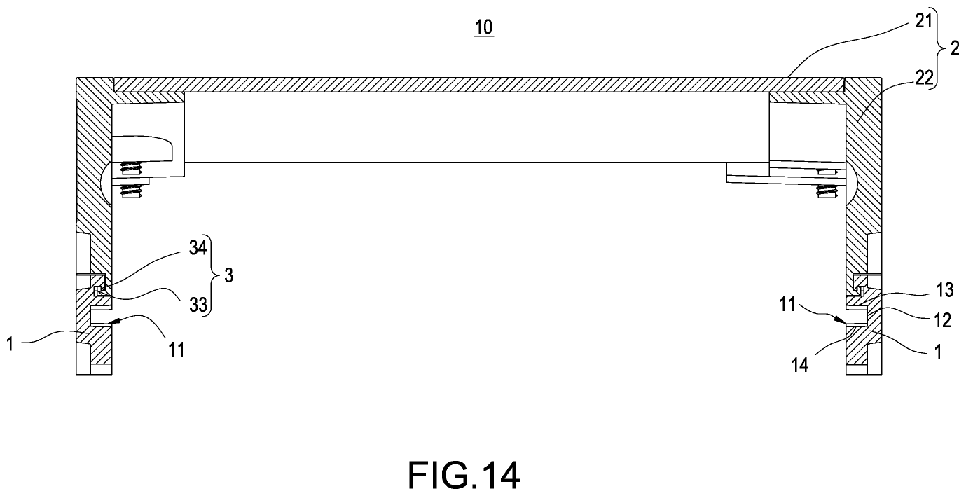

Please refer to FIG. 13 to FIG. 14, which depict the fourth embodiment of the air baffle structure 10 in this disclosure. The embodiment of FIG. 13 to FIG. 14 is similar to the embodiment of FIG. 1 to FIG. 9. The embodiment of FIG. 13 to FIG. 14 is different from the embodiment of FIG. 1 to FIG. 9 in the structure of the detachable components 3.

More detailed is as follows. Each of the detachable components 3 includes a strip 33 and a groove 34. The strip 33 is extended along the axial direction of either each of the brackets 1 or each of the side plates 22. The groove 34 is disposed along the axial direction of the other one between each of the brackets 1 and each of the side plates 22. In other words, if the strip 33 is disposed on the side plate 22, the groove 34 is disposed on the bracket 1, and vice versa. The strip 33 is engaged in the groove 34 in a horizontal direction. Therefore, the pair of brackets 1 and the pair of side plates 22 are assembled with each other through the pair of detachable components 3.

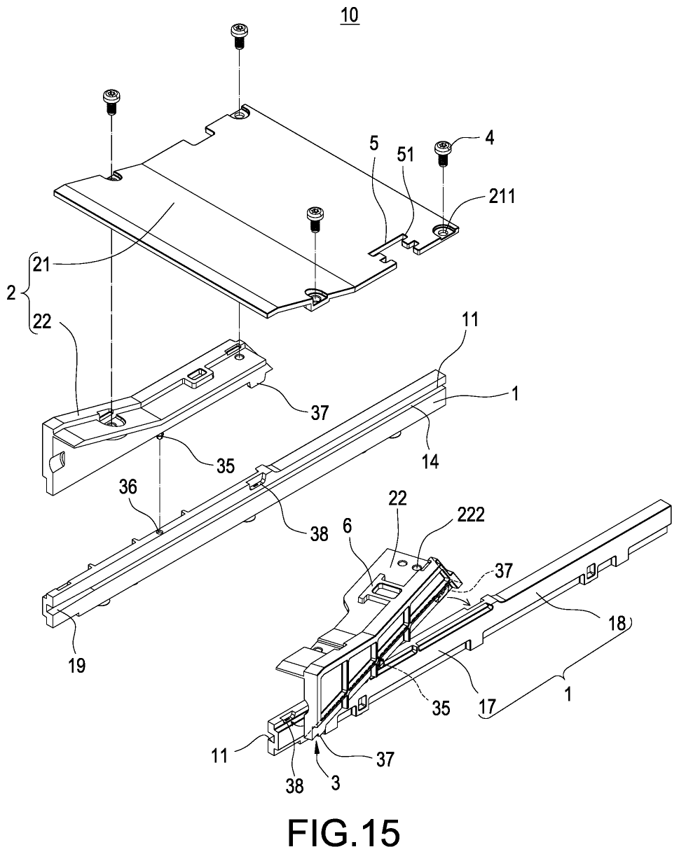

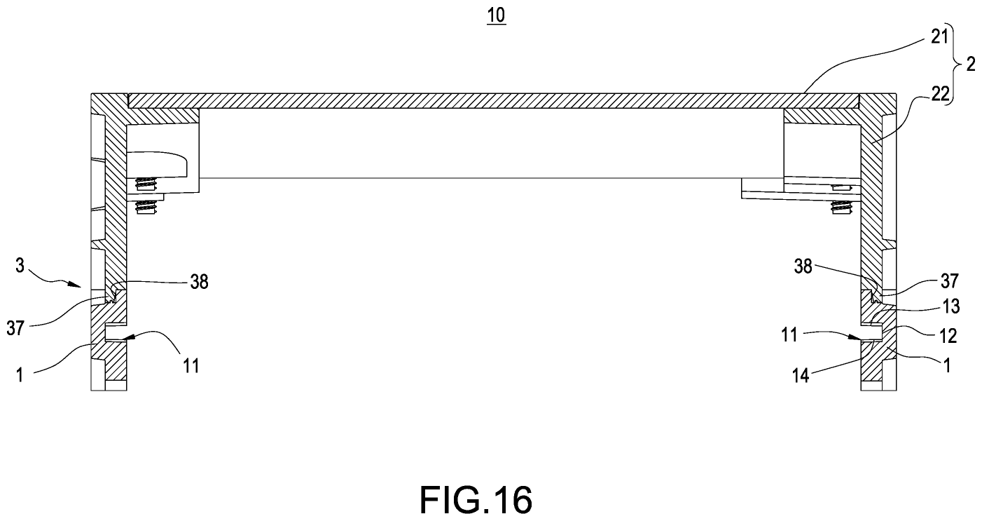

Please refer to FIG. 15 to FIG. 16, which depict the fifth embodiment of the air baffle structure 10 in this disclosure. The embodiment of FIG. 15 to FIG. 16 is similar to the embodiment of FIG. 1 to FIG. 9. The embodiment of FIG. 15 to FIG. 16 is different from the embodiment of FIG. 1 to FIG. 9 in the structure of the detachable components 3.

Further detailed is as follows. Each of the detachable components 3 includes a shaft 35, a pivot hole 36, two tenons 37 and two slots 38. The shaft 35 is protruded from either the top of the bracket 1 or the bottom of the side plate 22. The pivot hole 36 is recessed on the other one between the top of the bracket 1 and the bottom of the side plate 22. In other words, if the shaft 35 is disposed on the side plate 22, the pivot hole 36 is disposed on the bracket 1, and vice versa. Each of the two tenons 37 is extended from an inner side and an outer side of the bracket 1 or the side plate 22 to dispose on two sides of the shaft 35. Each of the two slots 38 is recessed on an inner side and an outer side of the other one between the bracket 1 and the side plate 22 to dispose on two sides of the shaft 35. In other words, if each of the two tenons 37 is disposed on the side plate 22, each of the two slots 38 is disposed on the bracket 1, and vice versa. The shaft 35 is vertically inserted and pivotally connected to the pivot hole 36. The tenon 37 is rotated around the shaft 35 with the side plate 22 to engage in the slot 38. Therefore, the pair of brackets 1 and the pair of side plates 22 are assembled to each other through the pair of detachable components 3.

While this disclosure has been described by means of specific embodiments, numerous modifications and variations could be made thereto by those skilled in the art without departing from the scope and spirit in this disclosure set forth in the claims.

What is claimed is:

1. An air baffle structure, configured for installing a motherboard and inside a case, the case comprising an opening, and the air baffle structure comprising:
a pair of brackets, fixed on the case and disposed on two sides of the opening, and the motherboard pluggably arranged between the pair of brackets; and
an air baffle cover, connected to tops of the pair of brackets and straddling the pair of brackets.

2. The air baffle structure according to claim 1, wherein the air baffle cover comprises a top plate and a pair of side plates connected to two sides of the top plates, and the pair of the side plates are detachably fixed to the tops of the pair of brackets.

3. The air baffle structure according to claim 2, wherein the air baffle cover comprises a first air opening disposed adjacent to the opening and a second air opening disposed away from the opening on two ends thereof, and a height of the top plate is gradually decreased from the first air opening toward the second air opening.

4. The air baffle structure according to claim 2, further comprising a pair of detachable components, wherein each of the detachable components comprises a plurality of posts and a plurality of sockets, and each of the posts is protruded from either the top of each of the brackets or a bottom of each of the side plates;
each of the sockets is recessed on another one between the top of each of the brackets and the bottom of each of the side plates; and
each of the posts is inserted in each of the sockets.

5. The air baffle structure according to claim 2, further comprising a pair of detachable components, wherein each of the detachable components comprises a strip and a groove;
the strip is extended along an axial direction of either each of the brackets or each of the side plates, and the groove is disposed along the axial direction of another one between each of the brackets and each of the side plates; and
the strip is engaged in the groove.

6. The air baffle structure according to claim 2, further comprising a pair of detachable components, wherein each of the detachable components comprises a shaft, a pivot hole, two tenons and two slots;
the shaft is protruded from either the top of each of the brackets or the bottom of each of the side plates;
the pivot hole is recessed on another one between the top of each of the brackets and the bottom of each of the side plates;
the shaft is connected pivotally to the pivot hole;
each of the two tenons is extended from an inner side and an outer side of either each of the brackets or the side plates to be disposed on two sides of the shaft;
each of the two slots is recessed on the inner side and the outer side of another one between each of the brackets and each of the side plates to be disposed on two sides of the shaft; and
each of the tenons is engaged in each of the slots.

7. The air baffle structure according to claim 2, wherein one of the pair of side plates is extended with an extension piece laminated with the top plate;
a zigzag groove is disposed on either the top plate or the extension piece, and a bump is extended on another one between the top plate and the extension piece; and
a plurality of recesses is disposed parallelly on an inner peripheral wall of the zigzag groove; and
the bump is embedded in the zigzag groove and selectively engaged with one of the recesses.

8. The air baffle structure according to claim 2, wherein a zigzag groove is disposed on either each of the brackets or each of the side plates, and a bump is disposed on another one between each of the brackets and each of the side plates;
a plurality of recesses is disposed parallelly on an inner peripheral wall of the zigzag groove; and
the bump is embedded in one of the zigzag grooves and selectively engaged with one of the recesses.

9. The air baffle structure according to claim 2, further comprising a plurality of fastening components, wherein the top plate comprises a plurality of first fastening holes, and each of the side plates comprises a plurality of second fastening holes; and
each of the fastening components is inserted and fixed in one of the first fastening holes and one of the second fastening holes.

10. The air baffle structure according to claim 1, wherein two rail guiding grooves are disposed on inner sides of the pair of brackets, and two sides of the motherboard are pluggably embedded in the rail guiding grooves; and
each of the rail guiding grooves comprises an inner side wall, an inner top wall and an inner bottom wall, and a plurality of elastic arms are protruded from the inner side wall;
each of the brackets comprises a plurality of hollow grooves disposed on an upper side and a lower side of the rail guiding groove; and
a plurality of elastic bulges is disposed on the inner top wall and the inner bottom wall corresponding to the plurality of hollow grooves.

11. The air baffle structure according to claim 10, wherein each of the rail guiding grooves comprises a flaring section adjacent to the opening, and an inner periphery size of the flaring section is gradually increased in a direction toward the opening.

12. The air baffle structure according to claim 1, wherein each of the brackets comprises a front section and a rear section, and the front section is disposed adjacent to the opening with respect to the rear section; and
the air baffle cover straddles between the front sections of the pair of brackets.

13. The air baffle structure according to claim 12, further comprising an auxiliary air baffle cover, wherein the auxiliary air baffle cover is connected to the tops of the pair of brackets and one end of the air baffle cover, and the auxiliary air baffle cover straddles between the rear sections of the pair of brackets.
